(19) United States
(12) Patent Application Publication
(10) Pub. No.: US 2026/0157178 A1
(43) Pub. Date: Jun. 4, 2026

(54) METAL-CERAMIC SUBSTRATE AND ELECTRONIC COMPONENT COMPRISING A METAL-CERAMIC SUBSTRATE

(71) Applicant: Heraeus Electronics GmbH & Co. KG, Hanau (DE)

(72) Inventors: Leszek NIEWOLAK, Hanau (DE); Ruzica DENADIC, Hanau (DE); Reinhold BAYERER, Reichelsheim (DE); Bastian SCHLÜTER, Hanau (DE); Richard WACKER, Hanau (DE)

(21) Appl. No.: 19/397,253

(22) Filed: Nov. 21, 2025

(30) Foreign Application Priority Data
Nov. 29, 2024 (EP) 24216356.6

(51) Int. Cl. H01L 23/373

(52) U.S. Cl. CPC H10W 40/255

(57) ABSTRACT

A metal-ceramic substrate and to an electronic component having a metal-ceramic substrate. The metal-ceramic substrate includes (i) a ceramic body, (ii) a metal layer which is bonded to the ceramic body in a planar manner. The metal layer comprises at least one recess, and a surface of the ceramic body is exposed through the recess. The surface of the ceramic body exposed through the recess comprises an active metal content of 0.5-15 wt. %.

### CROSS-REFERENCE TO RELATED APPLICATION

This application claims priority pursuant to 35 U.S.C. 119 (a) to European Application No. 24216356.6, filed Nov. 29, 2024, which application is incorporated herein by reference in its entirety.

### FIELD

The present invention relates to a metal-ceramic substrate and to an electronic component comprising a metal-ceramic substrate.

### BACKGROUND

Metal-ceramic substrates play an important role in the field of power electronics. They are a crucial element when building electronic components and ensure rapid dissipation of large quantities of heat during operation of said components. Metal-ceramic substrates typically consist of a ceramic layer and a metal layer which is bonded to the ceramic layer.

Several methods are known from the prior art for bonding the metal layer to the ceramic layer. In the so-called DCB (“direct copper bonding”) method, a copper foil is provided superficially with a copper compound (usually copper oxide), which has a lower melting point than copper, by reacting copper with a reactive gas (usually oxygen). When the copper foil treated in this way is applied to a ceramic body and the composite is heated, the copper compound melts and wets the surface of the ceramic body, so that a stable cohesive bond is created between the copper foil and the ceramic body. This method is described, for example, in U.S. Pat. No. 3,744,120 A or DE 2319854 C2.

In an alternative method, metal foils can be bonded to ceramic bodies at temperatures of approximately 650 to 1,000° C., wherein a special active solder is used, which contains a metal having a melting point of at least 700° C. (usually silver) and an active metal. The role of the active metal is to react with the ceramic material and to thus facilitate a bonding of the ceramic material to the remaining solder, forming a reaction layer, while the metal having a melting point of at least 700° C. serves to bond said reaction layer to the metal foil. For example, JP4812985 B2 proposes bonding a copper foil to a ceramic body using a solder containing 50 to 89 percent by weight silver, as well as copper, bismuth and an active metal. With this method, it is possible to attach the copper foil reliably to the ceramic body. Alternatively, silver-free active solders can be used to bond metal foils to ceramic bodies. These active solders are based, for example, upon high-melting metals (in particular copper), low-melting metals (such as bismuth, indium, or tin), and active metals (such as titanium). Such a technique is proposed, for example, in DE 102017114893 A1. This technique basically results in a new, independent class of compounds, since the basis of the solders used is formed by another metal (copper instead of silver), which leads to changed material properties and results in an adaptation with regard to the other solder components and modified joining conditions.

When constructing such actively soldered metal-ceramic substrates, the metal foil is usually first bonded to the ceramic material over its entire surface via the active solder. In a subsequent step, the metal-ceramic substrate is structured in order to create, for example, contact regions for semiconductor components (such as chips). For structuring, the metal-ceramic substrate is usually first treated with a first etching solution, with which the metal foil is removed in some regions. This is usually followed by treatment with a second etching solution in order to completely remove the remaining reaction layer containing active metal and thus to electrically isolate the individual contact regions from one another.

As part of electronic components, the metal-ceramic substrates produced in this way are usually exposed to high voltages during operation. With high voltages, the risk increases that the isolation between the contact regions will not be able to withstand the electrical load, and that a partial discharge will occur. In order to prevent this, it must therefore be ensured that the contact regions are sufficiently isolated from one another.

It would therefore be desirable to further increase the partial discharge resistance of metal-ceramic substrates.

### SUMMARY

An object of the present invention is therefore to provide a metal-ceramic substrate which has an increased partial discharge resistance.

This object is achieved by the metal-ceramic substrate of claim 1. The invention therefore provides a metal-ceramic substrate containing
(i) a ceramic body,
(ii) a metal layer which is bonded to the ceramic body in a planar manner, wherein the metal layer comprises at least one recess, and a surface of the ceramic body is exposed through the recess,

wherein the surface of the ceramic body exposed through the recess comprises an active metal content of 0.5-15 wt. %.

Furthermore, the invention relates to an electronic component comprising such a metal-ceramic substrate.

In addition, the invention relates to a method for producing a metal-ceramic substrate.

The metal-ceramic substrate according to the invention comprises a ceramic body.

The ceramic body is preferably a body formed from ceramic. The body can have any geometry, but is preferably designed as a cuboid. The ceramic body comprises boundary surfaces—in the case of a cuboid, six boundary surfaces. The ceramic body preferably comprises a primary boundary surface. The primary boundary surface in this document preferably refers to the boundary surface (very particularly preferably the boundary surface with the greatest surface area) which is connected to the metal layer over its surface. The primary boundary surface particularly preferably refers to the boundary surface (very particularly preferably, the boundary surface with the greatest surface area) which is bonded in a planar manner to the metal layer that comprises at least one recess. The primary boundary surface preferably lies in the primary extension plane of the ceramic body, or runs parallel to it. Accordingly, the main extension plane of the ceramic body is understood preferably to be a plane that runs in parallel with the primary boundary surface of the ceramic body or encloses it.

The ceramic of the ceramic body is preferably an insulating ceramic. According to a preferred embodiment, the ceramic is selected from the group consisting of oxide ceramics, nitride ceramics, and carbide ceramics. According to a further preferred embodiment, the ceramic is selected from the group consisting of metal oxide ceramics, silicon oxide ceramics, metal nitride ceramics, silicon nitride ceramics, boron nitride ceramics, and boron carbide ceramics. According to a particularly preferred embodiment, the ceramic is selected from the group consisting of aluminum nitride ceramics, silicon nitride ceramics, and aluminum oxide ceramics (such as ZTA (“zirconia-toughened alumina”) ceramics). According to a further very particularly preferred embodiment, the ceramic body consists of (1) at least one element selected from the group consisting of silicon and aluminum, (2) at least one element selected from the group consisting of oxygen and nitrogen, optionally (3) at least one element selected from the group consisting of (3a) rare earth metals, (3b) metals of the second main group of the periodic table of elements, (3c) zirconium, (3d) copper, (3e) molybdenum and (3f) silicon, and optionally (4) unavoidable impurities.

The ceramic body preferably has a thickness in the range of 0.05-10 mm, more preferably a thickness in the range of 0.1-5 mm, and particularly preferably a thickness in the range of 0.15-3 mm.

The metal-ceramic substrate according to the invention comprises a metal layer which is bonded to the ceramic body in a planar manner, wherein the metal layer comprises at least one recess, and a surface of the ceramic body is exposed through the recess.

The metal layer preferably comprises boundary surfaces. The metal layer preferably comprises a primary boundary surface. The primary boundary surface is preferably referred to herein as the boundary surface (very particularly preferably the boundary surface with the greatest surface area) which faces away from the ceramic body. The primary boundary surface preferably lies in the primary extension plane of the metal layer or runs parallel to it. Accordingly, the primary extension plane of the metal layer is preferably understood to be a plane that runs parallel to the primary boundary surface of the metal layer or encloses it. The primary boundary surface of the metal layer preferably runs parallel to the primary boundary surface of the ceramic body, and is particularly preferably spaced apart from it.

The metal layer preferably comprises at least one metal selected from the group consisting of copper and aluminum. According to a particularly preferred embodiment, the metal layer comprises copper. According to a further preferred embodiment, the metal layer comprises a reaction layer. The reaction layer preferably comprises an active metal. Preferably, the reaction layer is in contact with the ceramic body. Furthermore, the reaction layer is preferably in contact with the remainder of the metal layer. Therefore, the reaction layer is preferably located between the ceramic body and the remainder of the metal layer. According to a preferred embodiment, the reaction layer comprises a higher active metal content than the remainder of the metal layer. According to a further preferred embodiment, the proportion of copper is at least 60 wt. %, more preferably at least 65 wt. %, even more preferably at least 70 wt. %, and particularly preferably at least 75 wt. %, based upon the total weight of the metal layer.

The metal layer is preferably bonded to the ceramic body in a planar manner. Preferably, the metal layer is materially bonded to the ceramic body. According to a preferred embodiment, the metal layer is bonded to the ceramic body via an active soldering process. The active soldering process may, for example, be an AMB (active metal brazing) process. In the AMB process, the metal layer is bonded to the ceramic body, preferably materially bonded using an active solder. According to a preferred embodiment, the active solder comprises a metal M1 having a melting point of at least 700° C. The metal M1 is preferably copper. According to a further preferred embodiment, the active solder comprises a metal M2 having a melting point of less than 700° C. The metal M2 is preferably tin. According to an even further preferred embodiment, the active solder comprises a metal M3 selected from the group of active metals. The metal M3 is preferably selected from the group consisting of hafnium, titanium, zirconium, niobium, tantalum, vanadium, and cerium. The metal M3 is particularly preferably titanium. According to an even further preferred embodiment, the active solder comprises a metal M4 selected from the group consisting of bismuth, gallium, zinc, indium, germanium, aluminum, and magnesium. According to a preferred embodiment, the active solder comprises a silver content of less than 1.0 wt. % based upon the solids content of the active solder. According to an alternative embodiment, the active solder comprises a silver content of at least 50 wt. % based upon the solids content of the active solder. In the active soldering process, a reaction layer, via which the metal layer is materially bonded to the ceramic body, is preferably formed as part of the metal layer.

The metal layer is preferably bonded to the ceramic body in a planar manner. Accordingly, the metal layer is preferably bonded in a planar manner to the primary boundary surface of the ceramic body. The metal layer is preferably not bonded to the entire primary boundary surface of the ceramic body. In particular, it can be provided that the primary boundary surface of the ceramic body is larger than the surface of the metal layer bonded to the ceramic body. In these cases, the primary boundary surface of the ceramic body protrudes.

The metal layer preferably has a thickness in the range of 0.01-10 mm, particularly preferably a thickness in the range of 0.03-5 mm, and very particularly preferably a thickness in the range of 0.05-3 mm.

The metal layer comprises at least one recess, wherein a surface of the ceramic body is exposed through the recess. The at least one recess preferably electrically isolates separate regions of the metal layer from one another. The metal layer, which comprises at least one recess, can also be referred to as a structured metal layer. Semiconductor components can be attached to the structured metal layer. The at least one recess is preferably created by treating the metal layer with at least one etching solution and/or with radiant energy.

A recess is preferably understood to mean a region of the metal layer that is obtained by removing material from the metal layer. Preferably, a recess is a region which is freed from material of the metal layer and is located between adjacent (particularly preferably in the main extension plane of the metal layer) regions of the metal layer. Therefore, a recess is preferably present between two adjacent regions of a metal layer.

The surface of the ceramic body exposed through the recess preferably comprises material of the ceramic body. The surface of the ceramic body exposed through the recess comprises active metal. The active metal preferably comes from a reaction layer created during the active soldering process. The active metal is preferably present as a reaction product with elements of the ceramic material. According to a preferred embodiment, the active metal is present as an active metal compound. The active metal compound is preferably selected from the group consisting of active metal nitrides, active metal silicides, and active metal aluminides. The active metal compound is particularly preferably titanium nitride, titanium silicide, or titanium aluminide. The active metal is preferably selected from the group consisting of hafnium, titanium, zirconium, niobium, vanadium, tantalum, cerium, and mixtures thereof. According to a particularly preferred embodiment, the active metal is titanium.

According to the invention, the surface of the ceramic body exposed through the recess comprises an active metal content of 0.5-15 wt. %. According to a preferred embodiment, the surface of the ceramic body exposed through the recess comprises a content of 0.6-14 wt. %. The active metal content of the surface of the ceramic body exposed through the recess is preferably determined by scanning electron microscopy-energy dispersive X-ray spectroscopy (SEM-EDX).

Surprisingly, it has been found that the partial discharge resistance of a metal-ceramic substrate is significantly increased if the surface of the ceramic body exposed through the recess comprises an active metal content of 0.5-15 wt. %.

According to a further preferred embodiment, the surface of the ceramic body exposed through the at least one recess comprises active metal islands. The term “active metal island” is preferably understood to mean regions with an accumulation of active metal that can be distinguished in an image obtained by means of scanning electron microscopy-energy dispersive X-ray spectroscopy (SEM-EDX) (preferably as described under test methods).

According to yet another preferred embodiment, the active metal islands have an average area in the range of 5-65 μm². The active metal islands particularly preferably have an average area in the range of 10-65 μm² and very particularly preferably an average area in the range of 10-60 μm².

According to yet another preferred embodiment, the active metal islands are spaced apart from one another on average by at least 2 μm.

The active metal islands are preferably spaced apart from one another on average by at least 2 μm, particularly preferably at least 3 μm, and very particularly preferably at least 4 μm. The active metal islands are preferably spaced apart from one another on average by less than 20 μm, particularly preferably less than 18 μm, and very particularly preferably less than 15 μm. According to a preferred embodiment, the active metal islands are spaced apart from one another on average by 2-20 μm, particularly preferably 3-18 μm, and very particularly preferably 4-15 μm.

Surprisingly, it has been found that creating active metal islands that
(A) have an average area in the range of 5-65 μm², and
(B) are spaced apart from one another on average by at least 2 μm,

can further increase the partial discharge resistance.

According to a preferred embodiment, the metal-ceramic substrate comprises a further (second) metal layer which is connected in a planar manner to the ceramic body. The further metal layer is preferably connected in a planar manner to the boundary surface facing away from the primary boundary surface of the ceramic (and preferably running in parallel therewith). The further (second) metal layer can be of the same nature as the (first) metal layer or can differ in its properties from the (first) metal layer. For the properties of the further (second) metal layer, reference is made to the above explanations regarding the (first) metal layer.

The metal-ceramic substrate according to the invention can in particular be used for applications in electronics, especially for the field of power electronics.

The invention therefore also provides an electronic component which comprises the metal-ceramic substrate according to the invention.

According to a preferred embodiment, the electronic component comprises the metal-ceramic substrate according to the invention and at least one semiconductor component. The at least one semiconductor component is preferably bonded to the (first) metal layer in a planar manner.

According to a further preferred embodiment, the metal-ceramic substrate of the electronic component comprises a further (second) metal layer. The further (second) metal layer is preferably bonded over its surface to the ceramic body. In this case, the further metal layer is preferably bonded over its surface to the boundary surface of the ceramic body facing away from the primary boundary surface of the ceramic body (and preferably running parallel thereto).

According to a further preferred embodiment, the electronic component comprises a heat sink. This heat sink is preferably bonded in a planar manner to the further (second) metal layer of the metal-ceramic substrate. Alternatively, the further (second) metal layer of the metal-ceramic substrate can be designed as a heat sink.

According to a further preferred embodiment, the electronic component comprises a metal-ceramic substrate, which comprises a (first) metal layer and a further (second) metal layer (wherein the further metal layer is preferably bonded in a planar manner to the boundary surface facing away from the primary boundary surface of the ceramic body), a heat sink, and at least one semiconductor component, wherein the at least one semiconductor component is bonded in a planar manner to the first metal layer of the metal-ceramic substrate, and the heat sink is bonded in a planar manner to the further (second) metal layer of the metal-ceramic substrate.

The metal-ceramic substrate according to the invention can be obtained by different manufacturing processes.

The invention also relates to a method for producing a metal-ceramic substrate according to the invention.

The method for producing the metal-ceramic substrate comprises the steps of:
a) providing a metal-ceramic substrate comprising
(B) a1) a ceramic body and
(C) a2) a metal layer bonded in a planar manner to the ceramic body, and

b) creating at least one recess in the metal layer, wherein a surface of the ceramic body is exposed through the recess, and the surface of the ceramic body exposed through the recess comprises an active metal content of 0.5-15 wt. %.

In step a), a metal-ceramic substrate is first provided.

This metal-ceramic substrate comprises a ceramic body and a metal layer that is bonded in a planar manner to the ceramic body. The metal-ceramic substrate can be a standard metal-ceramic substrate. The ceramic body and the metal layer may comprise a composition as described above with respect to the metal-ceramic substrate. The metal layer can preferably be materially bonded to the ceramic body, as also described above with respect to the metal-ceramic substrate. The material bond is preferably made via an active soldering process, in particular an AMB process. According to a preferred embodiment, the metal-ceramic substrate is therefore a metal-ceramic substrate produced in an active soldering process, in particular an AMB process.

In step b), a recess is created in the metal layer, wherein a surface of the ceramic body is exposed through the recess, and the surface of the ceramic body exposed through the recess comprises an active metal content of 0.5-15 wt. %

The recess in the metal layer is preferably created in order to separate individual portions of the metal layer from one another and thus electrically isolate them. The recess therefore exposes a surface of the ceramic body.

The recess can basically be created in a manner customary in the art. Preferably, the recess is created by at least one removal process selected from the group consisting of etching, introduction of radiant energy, and mechanical removal (for example, wet blasting, dry blasting, or milling). Particularly preferably, the recess is created by at least one removal process selected from the group consisting of etching and introduction of radiant energy.

According to a preferred embodiment, the recess is created by etching.

For this purpose, an etching mask is preferably first applied to the metal layer. The etching mask serves to protect the masked regions of the metal layer from etching in an etching step. This ensures that only those regions of the metal layer of the metal-ceramic substrate that are unmasked and intended for creating the recess are accessible for etching. Consequently, the etching mask is designed in such a way that no etching of the masked regions of the metal layer occurs during the etching step. The type of etching mask is not limited further. The etching mask can, for example, be a standard negative mask or positive mask. Standard etching resists can be used to produce the etching mask. These etching resists preferably contain a curable polymer (for example a light-curable polymer) and can be applied to the metal layer, for example, as a film (for example as a dry film) or as a liquid (for example by printing or spraying). After application, the etching resists can be treated in a suitable manner (e.g., cured by light irradiation) to obtain the etching mask. According to one possible embodiment, a photosensitive film is applied to the metal layer of the metal-ceramic substrate, and is then exposed to the areas to be masked in order to obtain the etching mask. The unexposed regions of the photosensitive film can then be removed in a conventional manner (for example using a sodium carbonate solution).

Etching is preferably carried out in a step b1 (etching) and a step b2 (etching).

In step b1 (etching), unmasked regions of the metal layer are preferably etched to obtain a recess. Etching is preferably carried out in a standard, conventional manner. Etching is therefore preferably carried out using a standard etching solution. According to a preferred embodiment, the etching solution is selected from the group consisting of FeCl₃ etching solutions and CuCl₂ etching solutions.

After etching in step b1 (etching), a reaction layer containing active metal may still be present on the ceramic body if, for example, the metal-ceramic substrate was produced according to an AMB process using an active solder. In this case, the metal layer is usually removed down to the reaction layer by conventional etching solutions so that the underlying surface of the ceramic body is not yet exposed, and the otherwise separate regions of the metal layer continue to be electrically bonded to one another via the remaining reaction layer.

Therefore, in a step b2 (etching), the reaction layer remaining and exposed in step b1 (etching) is preferably partially removed by further etching.

Further etching is preferably carried out using a further (second) etching solution. The further etching solution can be selected from the group consisting of etching solutions containing hydrogen peroxide and etching solutions containing ammonium peroxodisulfate. For example, the further etching solution may be an etching solution containing ammonium fluoride and fluoroboric acid (for example HBF₄) as well as hydrogen peroxide and/or ammonium peroxodisulfate.

After step b2 (etching), the etching mask is preferably removed. The etching mask can be removed in a standard manner. For this purpose, the metal-ceramic substrate can be treated, for example, with an alkaline solution (e.g., a 2.5% sodium hydroxide solution).

According to a further preferred embodiment, the recess is created by a combination of etching and introducing radiant energy.

In step b1 (etching), unmasked regions of the metal layer are preferably etched to obtain a recess as shown above.

In step b2 (radiation), the reaction layer remaining and exposed in step b1 (etching) is preferably partially removed by introducing radiant energy.

Radiant energy is preferably introduced using an ultrashort pulse laser (for example, an IR picosecond or femtosecond laser). An ultrashort pulse laser is a laser that can emit laser pulses with a pulse duration in the range of picoseconds (“picosecond laser”) or femtoseconds (“femtosecond laser”). The pulsed laser beam of the ultrashort pulse laser, for example, comprises laser pulses with a pulse duration in the range of picoseconds (“picosecond laser”) or femtoseconds (“femtosecond laser”). For example, the pulse duration is 1 fs to 100 ps (e.g., 1 to 100 ps or 1 to <1000 fs).

In this case, the etching mask can be removed after or even before step b2 (radiation) in a conventional manner—for example, as described above.

According to a further preferred embodiment, the recess is created by introducing radiant energy.

In a step b (radiation), a recess is preferably created by partially removing the metal layer including the reaction layer containing the active metal.

Radiant energy is preferably introduced using an ultrashort pulse laser (for example, an IR picosecond or femtosecond laser), as described above. If the recess is created by introducing radiant energy, the application of an etching mask can be dispensed with.

In step b), the parameters for creating a recess in the metal layer are preferably selected directly such that a surface of the ceramic body is exposed through the recess, and the surface of the ceramic body exposed through the recess comprises an active metal content of 0.5-15 wt. %. Likewise, the parameters for creating a recess in the metal layer are preferably selected directly such that the surface of the ceramic body exposed through the at least one recess comprises active metal islands, and the active metal islands have an average area in the range of 5-65 μm² and/or the active metal islands are spaced apart from one another on average by at least 2 μm.

If the recess in the metal layer is created by etching, in step b2 (etching), the concentration of the further (second) etching solution, the exposure time of the metal-ceramic substrate provided in step b1 (etching) to the further (second) etching solution, and the treatment temperature and treatment time are in particular determinant for the active metal content of the surface of the ceramic body exposed through the recess as well as the presence and properties of the active metal islands. The parameters required for setting the value according to the invention can be ascertained, for example, by a simple series of tests in which the concentration of the further (second) etching solution, the exposure time to the further (second) etching solution, and the treatment temperature and treatment time are varied.

If the recess in the metal layer is created by introducing radiant energy, in step b (radiation) or in step b2 (radiation), the total fluence of the preferably used ultrashort pulse laser is in particular determinant for the active metal content of the surface of the ceramic body exposed through the recess as well as the presence and properties of the active metal islands. The laser parameters required for setting the value according to the invention can be ascertained, for example, by a simple series of tests in which the laser fluence is varied.

The method described herein makes it possible to obtain a metal-ceramic substrate that has high partial discharge resistance.

### BRIEF DESCRIPTION

The invention is described below with reference to a FIGURE, which, however, is not to be understood as limiting.

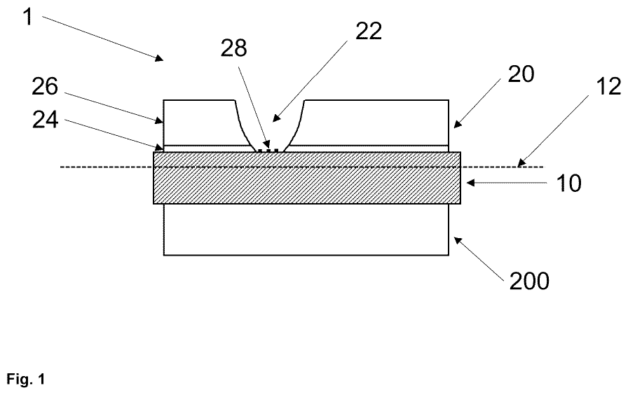

FIG. 1 shows the side view of a metal-ceramic substrate according to the invention (not to scale).

### DETAILED DESCRIPTION

The metal-ceramic substrate 1 shown in FIG. 1 comprises a ceramic body 10 (with a main extension plane 12) and a metal layer 20. The metal layer 20 is bonded in a planar manner to the primary boundary surface of the ceramic body 10. In the embodiment according to FIG. 1, the metal-ceramic substrate 1 further comprises a further metal layer 200 which is bonded to the ceramic body 10 in a planar manner. The metal layer 20 comprises a reaction layer 24 and a remainder of the metal layer 26. The reaction layer 24 preferably comprises an active metal and is in contact with the ceramic body 10. Furthermore, the reaction layer 24 is in contact with the remainder of the metal layer 26. The metal layer 20 comprises a recess 22, which exposes the surface of the ceramic body 10. The surface of the ceramic body 10 exposed through the recess 22 comprises an active metal content of 0.5-15 wt. %. The active metal is preferably present in the form of active metal islands 28. The active metal islands 28 have an average area in the range of 5-65 μm² and are spaced apart from one another on average by at least 2 μm.

### Test Methods

### 1. Determination of the Active Metal Content in the Surface of the Ceramic Body Exposed Through the Recess

The active metal content of the surface of the ceramic body exposed through the recess is preferably determined by scanning electron microscopy-energy dispersive X-ray spectroscopy (SEM-EDX).

In SEM-EDX, a focused primary electron beam is guided (scanned) over the sample surface point by point. The backscattered electrons and the secondary electrons are detected by the detectors in the SEM chamber, wherein the number of electrons per pixel results in a microscopic image of the sample surface in grayscale. In addition, the primary electron beam excites the sample to emit characteristic X-ray radiation, wherein the elements in the sample and their proportion by weight can be determined by analyzing the energy spectrum using an EDX detector.

A scanning electron microscope (for example, Gemini Ultra 55, ZEISS Ltd) with a silicon drift EDX detector (for example, Ultimax 100, Oxford Instruments) and analysis software (for example, AZtec, Oxford Instruments) is preferably used for the examination. In order to prepare for the examination, the sample surface is first coated with a very thin (a few nm thick) carbon layer (for example, with the SCD 005 sputter coater with CEA 035 carbon evaporation supply, BalTec AG). The sample is then positioned in the sample chamber, and the chamber is placed under vacuum. The examination is subsequently carried out by means of SEM-EDX. The following settings are preferably used: magnification: 100×, 500×, and 1,000×; acceleration voltage=15 kV. A separate EDX spectrum is recorded for each point measured on the sample surface. All recorded EDX spectra are processed by the analysis software in order to determine a quantitative chemical composition for each point. This allows the average content of elements (for example, of the active metal) in the sample surface to be determined quantitatively. The content of the elements is determined both in atomic percent and in percent by weight, with the total amount being 100%. The analysis is preferably carried out at 100× magnification.

### 2. Determination of Area and Distance Between the Active Metal Islands

The active metal islands are preferably determined by means of scanning electron microscopy-energy dispersive X-ray spectroscopy (SEM-EDX), as described above (under “Determination of the active metal content in the surface of the ceramic body exposed through the recess”). In an image obtained by means of SEM-EDX, the active metal islands are identified as distinguishable regions with an accumulation of active metal. The analysis software uses the data obtained by means of SEM-EDX to compile an electron microscopic image (EDX mapping). EDX mapping is used to represent the spatial distribution of selected elements (for example, active metal islands) on the sample surface. The areas and distances between the active metal islands are preferably evaluated by means of the software ImageJ (1.53c). For this purpose, the active metal islands are preferably surrounded by a contour line each. The surface area of the relevant regions enclosed by the contour line is then output by the software. The shortest distances between two adjacent active metal islands are subsequently determined in each case by drawing a straight line that connects the two contour lines. The length of each straight line is also output by the software.

In total, at least three SEM-EDX measurements per sample are preferably evaluated. Preferably, all active metal islands visible in the image are evaluated as described above. The average area of the active metal islands and the average distance between the active metal islands are preferably specified as arithmetic means of all active metal islands visible in the images.

### EXEMPLARY EMBODIMENTS

The present invention is described in more detail below by means of exemplary embodiments, which, however, should not be understood as limiting.

### 1. Production

For producing metal-ceramic substrates of Examples 1 to 5 and Comparative Examples 1 and 2, copper-ceramic substrates were used in which a ceramic body made of a silicon nitride ceramic with the dimensions 177.8×139×0.32 mm was in each case bonded on both sides to a copper layer with the dimensions 170×132×0.3 mm via an AMB (active metal brazing) process. The copper-ceramic substrates each had a titanium-containing reaction layer, which was due to the use of a titanium-containing active solder in the production of the copper-ceramic substrates.

These copper-ceramic substrates were first cleaned after production. A photosensitive film was then applied to both copper layers of the copper-ceramic substrates by means of a hot roll laminator. The photosensitive film was exposed to 30 mJ/cm² in each of the areas to be masked in order to harden the polymer contained in the photosensitive film and to obtain an etching mask. The unexposed regions of the photosensitive film were then removed chemically using a sodium carbonate solution (concentration=10 g/l). After applying the etching mask, the copper-ceramic substrates were cleaned by rinsing. Subsequently, the unmasked regions of the copper layers of the copper-ceramic substrates were chemically etched. For this purpose, the copper-ceramic substrates were sprayed in an etching system with a hydrochloric-acid copper chloride solution (copper ion content=160 g/l) containing hydrogen peroxide. Etching was carried out at a temperature of 50° C. and a spray pressure of 2.8 bar. By etching, material was removed from the unmasked regions of the copper layers of the copper-ceramic substrates. The copper-ceramic substrates were then rinsed.

Subsequently, unmasked regions of the titanium-containing reaction layer contained in the copper-ceramic substrates were also wet-chemically etched. For this purpose, the copper-ceramic substrates were again sprayed in an etching system with an etching solution containing ammonium fluoride, fluoroboric acid, and hydrogen peroxide. The contact time with the etching solution was varied for the individual copper-ceramic substrates in order to obtain the measured titanium residues in Table 1. The copper-ceramic substrates were subsequently rinsed and dried. The etching mask was then removed in a stripping system using a 2.5% sodium hydroxide solution.

The copper-ceramic substrates produced in this way each had a large contact region of copper with an area of 200 mm² and a small contact region of copper with an area of 20 mm² on the front side of the ceramic body, wherein the copper contact regions were separated from one another by a 1.2 mm wide recess. The distance between the copper contact regions and the outer edges of the ceramic body was 0.8 mm (as a peripheral edge) in each case. The rear side of the ceramic body was in each case coated over its entire surface with copper, wherein the distance between the copper coating and the outer edges of the ceramic body was 0.8 mm (as a peripheral edge) in each case.

### 2. Properties of the Copper-Ceramic Substrates

The titanium content of the surface of the ceramic body exposed through the recess was determined for the produced copper-ceramic substrates by means of scanning electron microscopy-energy dispersive X-ray spectroscopy (SEM-EDX) according to the test procedure described above. The titanium islands were also identified in an electron microscopic image, and the areas and distances between the titanium islands were examined according to the test procedure described above. The results are shown in Table 1.

TABLE 1
Titanium content, average area of the titanium islands and average
distance between the titanium islands in the recesses of the copper-
ceramic substrates produced in the exemplary embodiments.

| | | | Average |
|---|---|---|---|
| | Titanium | Average area | distance |
| | content | of the | between the |
| | in recess | titanium islands | titanium islands |
| | (in wt. %) | (in μm²) | (in μm) |
| Example 1 | 0.8 | 12 | 13.5 |
| Example 2 | 1.8 | 18 | 11.5 |
| Example 3 | 5.1 | 25 | 8.6 |
| Example 4 | 10.7 | 38 | 7.2 |
| Example 5 | 14.0 | 60 | 5.6 |
| Comparative | <0.5 | <5 | >20 |
| Example 1 | | | |
| Comparative | 15.9 | 66 | 1.4 |
| Example 2 | | | |

### 3. Evaluation

The copper-ceramic substrates obtained in Examples 1 to 5 and Comparative Examples 1 and 2 were examined for their partial discharge resistance (contact region/contact region and top/bottom).

For this purpose, the copper-ceramic substrates were clamped in insulating frames that completely enclosed the top and bottom sides at the edge and thus isolated the top sides from the bottom sides of the copper-ceramic substrates. A central recess in the insulating frame made it possible to contact the individual contact regions on the top and bottom sides of the copper-ceramic substrates by means of spring contacts. Subsequently, the copper-ceramic substrates thus contacted were placed in a plastic container filled with an insulating liquid (Galden HS 240), such that the individual contact regions were completely covered with the insulating liquid. The spring contacts protruding from the insulating liquid were connected to the measurement and analysis system MPD 600 (OMICRON Electronics). The partial discharge was measured in accordance with the IEC 61287 standard with a different operating voltage of 3.6 kV (50 Hz) (instead of 2.4 kV). (The alternating voltage was increased to 3.6 kV within 10 s and applied for 60 s. The partial discharge values indicated were ascertained in the last 10 s by averaging.)

For determining the partial discharge between the top and bottom sides of the copper-ceramic substrates (top/bottom), the operating voltage was applied to all contact regions on the front side, while the rear-side metallization was set to GND potential.

In order to determine the partial discharge between the copper contact regions (contact region/contact region), the operating voltage was applied to the large copper contact region, while the small copper contact region was set to GND potential together with the rear-side metallization in order to prevent charging effects of the rear-side metallization.

The results are shown in Table 2.

TABLE 2
Partial discharge resistance of the copper-ceramic
substrates produced in the exemplary embodiments.

Partial discharge resistance (in pC)

| | Contact region/ | Top/ |
|---|---|---|
| Examples | Contact region | Bottom |
| Example 1 | 0.06 | 0.07 |
| Example 2 | 0.07 | 0.07 |
| Example 3 | 0.08 | 0.07 |
| Example 4 | 0.08 | 0.09 |
| Example 5 | 0.09 | 0.09 |
| Comparative | 0.12 | 0.11 |
| Example 1 | | |
| Comparative | Voltage | Voltage |
| Example 2 | breakdown | breakdown |

The results show that the copper-ceramic substrates according to the invention of Examples 1 to 5 are clearly superior to the copper-ceramic substrates of Comparative Examples 1 and 2 with regard to the partial discharge resistance.

### LIST OF REFERENCE NUMERALS

1 Metal-ceramic substrate
10 Ceramic body
12 Main extension plane of the ceramic body
20 Metal layer
22 Recess
24 Reaction layer
26 Remainder of the metal layer
28 Active metal islands
200 Further metal layer

What is claimed is:

1. A metal-ceramic substrate, comprising
(i) a ceramic body;
(ii) a metal layer which is bonded to the ceramic body in a planar manner,
wherein the metal layer comprises at least one recess, and a surface of the ceramic body is exposed through the recess;
wherein the surface of the ceramic body exposed through the recess comprises an active metal content of 0.5-15 wt. %.

2. The metal-ceramic substrate according to claim 1, wherein the surface of the ceramic body exposed through the at least one recess comprises active metal islands, and the active metal islands fulfill at least one of the following features:
(A) the active metal islands have an average area in the range of 5-65 μm²; and
(B) the active metal islands are spaced apart from one another on average by at least 2 μm.

3. The metal-ceramic substrate according to claim 1, wherein the ceramic of the ceramic body is selected from the group consisting of aluminum nitride ceramics, silicon nitride ceramics, and aluminum oxide ceramics.

4. The metal-ceramic substrate according to claim 1, wherein the metal layer comprises copper.

5. The metal-ceramic substrate according to claim 1, wherein the active metal is selected from the group consisting of hafnium, titanium, zirconium, niobium, vanadium, tantalum, and cerium.

6. An electronic component comprising a metal-ceramic substrate according to claim 1.
